(19) United States
(12) Patent Application Publication
(10) Pub. No.: US 2008/0210545 A1
(43) Pub. Date: Sep. 4, 2008

(54) Method and Apparatus for Producing Electric Discharges

(76) Inventor: Vladimir Kouznetsov, Nynashamn (SE)

Correspondence Address: NIXON & VANDERHYE, PC, 901 NORTH GLEBE ROAD, 11TH FLOOR, ARLINGTON, VA, 22203, US

(21) Appl. No.: 11/666,636

(22) PCT Filed: Nov. 2, 2005
(86) PCT No.: PCT/SE05/01644

§ 371 Date: Apr. 3, 2008

(30) Foreign Application Priority Data
Nov. 2, 2004 (SE) 0402644-9

(51) Int. Cl. C23C 14/22

(52) U.S. Cl. 204/192.12; 372/55

(57) ABSTRACT

In producing discharges in a load element such as a magnetron sputtering device, electric pulses are provided from different electric pulse sources, e.g. three or more electric pulse sources. The pulse sources are controlled by a control and monitoring unit to give the element electric pulses different heights and start and end times. The element electric pulses are summed, such as by connecting the pulse sources in parallel to the load, to form resulting, relatively long electric pulses. Each of the resulting electric pulses can have a portion that has a substantially constant level and then the substantially constant level is formed from at least two element electric pulses having the same pulse height. The resulting electric pulses are applied to electrodes in the load. The element electric pulses can have the same polarity such as being half a period of a sinusoid oscillation of a single frequency. Then the time intervals between starts of successive element electric pulses are relatively short such as not being not larger than one third of the period of the sinusoid. For example, the resulting electric pulses can have a substantially rectangular shape, a shape including two different substantially constant levels or have a substantially triangular shape.

### TECHNICAL FIELD

The present invention relates to methods and apparatus for producing electric discharges between electrodes and also to apparatus in which such discharges are used. In particular it relates to producing discharges in a gas and/or in a vapor of a solid material, such as between the anode and the cathode in laser tubes, flashlamps and magnetron sputtering devices.

### BACKGROUND

Methods and devices for producing electric discharges between two electrodes are widely used in different areas of science and technology.

Electric discharges can be classified according to the magnitude of the current driving the discharges, see J. D. Roth, Industrial Plasma Engineering. Vol. 1: Principles, Bristol and Philadelphia, Institute of Physics Publishing, 1995. The mentioned classes of electric discharges include dark discharges, glow discharges and arc discharges. Electric discharges also can be classified according to the time variation of the current driving the discharges. In such a classification one can distinguish between direct current discharges and pulsed discharges. The difference between DC discharges and pulsed discharges is in a sense a general matter of convention since e.g. pulsed unipolar discharges can be considered as a periodically interrupted DC discharge or an amplitude modulated DC discharge. So, one can say that this other classification is more related to the principles of operation and design of the power supply driving the discharges. Hereinafter, electric discharges such as glow and arc discharges will be discussed as pulsed discharges.

The main problems arising after a voltage has been applied to discharge electrodes include

igniting a discharge and achieving the desired kind of discharge,

maintaining the desired kind of discharge, i.e. preventing/suppressing transition of one kind of discharge into another kind, and

achieving a high efficiency of the use of energy used for producing the discharges, which is, as is conventional, initially stored in a capacitive and/or an inductive energy accumulator.

In published U.S. patent applications Nos. 2003/0057875 and 2002/0149326 for M. Inochkin a method of producing electric arc discharges in a pulsed flashlamp is described. The described method is mainly directed to medical applications such as dermatology and cosmetology. The discharge is first established in a low current density simmer mode, a glow discharge mode, before transfer to arc mode. A high voltage, for example 8 kV, is used for initial lamp ionization. It results in lamp break down which is then maintained by a DC simmer current discharge that is used in order to avoid premature failure of the lamp. The current from the simmer source is generally less than 1 Ampere and may by in the magnitude of order of a tenth of 1 Ampere or less. For the main discharge an arc type discharge is used. The average arc discharge current is about 250 Amperes or more. The duration of discharge can be up to several hundreds of milli-seconds. The efficiency of utilization of the energy initially stored in a capacitor is about 90% that is substantially greater than the 20-50% energy utilization that is typical of prior art methods.

D. V. Mozgrin has in “High-Current Low-Pressure Quasi-Stationary Discharge in a magnetic field: Experimental Research”, Plasma Physics Reports, Vol. 21., No 5, 1995, pp. 400-409, translated from Fizika Plasmy, RU, Vol. 21, No. 5, 1995, pp. 422-433, original Russian text copyright 1995 for Mozgrin, described pulsed glow and arc discharges produced between an anode and a magnetron sputtering cathode.

To generate the electrical energy necessary for producing discharges between electrodes, such as in conductive media, in gases and/or vapors of solids, specialized electric power supply devices are used which for the case of applying pulses can be called pulsed power supply devices, pulsed power supplies or simply pursers. The apparatus in which the discharges are produced and thus contains the discharge electrodes is called a discharge unit. Generally, the discharge units are of the diode kind and can be divided in two main classes, discharge units employing a magnetic field created by external permanent magnets or electromagnets and discharge units operating without any external, applied magnetic field. Obviously, an internal magnetic field is always produced by the discharge current. Generally, pulsers used for both types of discharge units are based on the same principles.

Discharge units operating without a magnetic field and including or connected to corresponding pulsers include pulsed lasers tubes, pulsed lamps for medical purposes and for laser excitation, pulsed welding, X-ray and neutron sources, discharge units for cardiology for emergency medical treatment for preventing death from sudden cardiac arrest and various devices in many other applications.

Discharge units operating with an external magnetic field are used in science for pulsed electrons acceleration in electron accelerators, for plasma generation and plasma investigations and in technology for surface modification of work pieces using vapors and plasmas of solid substances, gases, and in various applications using electrons and ions beams.

Generally, the power supply devices or pulsers for producing pulsed discharges are based on components accumulating electric or magnetic energy that are rapidly discharged over an associated discharge unit. As has been said above, the discharge units can be used for producing vapors of solid materials and for excitation and ionization of gases and vapors. In order to produce these processes the power of the pulsed discharges has to be of the magnitude of order of tenths of a kilowatt up to megawatts. It is not possible to produce pulses having an extremely high power with a high repetition frequency since the average power of the produced pulses must be maintained at a level not causing an extreme heating of the pulser or of the discharge unit. Therefore the ratio of pulse time to time between pulses, i.e. the duty cycle, generally is low and is in the range of (10⁻⁵-10)%.

Pulsed lasers such as copper vapor lasers, excimer lasers and carbon dioxide lasers require a discharge tube for providing energy for excitation and a pulsed power supply device for causing the discharge tube to emit light. In U.S. patent application No. 2002/0003820 for D. Yoshida a discharge circuit for a pulsed laser and a pulsed power source are disclosed that are related to an improvement to a discharge circuit for a pulsed laser, for effecting pulsed laser oscillation by pulsed discharges at a prescribed repetition cycle so as to excite a laser medium, wherein variations in laser output caused by overshoot current at the time of discharges are eliminated. A discharge circuit comprising a power source, main discharge electrodes for generating a laser beam, a main discharge capacitor charged and then discharged for generating the main discharges between the main discharge electrodes, and a switching circuit for performing switching operations to charge the main discharge capacitor supplied from the power source in a prescribed repetition cycle, is provided, in parallel to the main discharge capacitor, with a circuit element for consuming or grounding the reverse current from the power source caused by overshoot generated directly after the main discharge, thereby attaining a stable laser output without adverse effects obtained from the overshoot voltage directly following a discharge.

Pulsed flashlamps, in particular Xe-filled flashlamps, are used in variety of applications, including pumping various gas or other laser devices, in various photo, copying, optical detection and optical ranging applications, in cosmetology and in various dermatology and other medical applications. Such lamps normally operate at high peak power. In order to achieve high power, the power supplies or drivers typically employ a storage capacitor, which is charged between lamp flashes or pulses, in series with an inductor and some type of switch.

In the U.S. patent applications Nos. 2003/0057875 and 2002/0149326 cited above flashlamp drive circuits are disclosed which utilize a two-core component having common windings as both an inductor for arc mode drive and for breakdown triggering of the lamp. The discharge of a capacitor through the inductor and the lamp is controlled by a high-speed semiconductor switch that is turned on and off by a suitable control unit, current flowing from the inductor along a one-way path including the lamp when the switch is off The control maintains the ratio of the variations of the current through the lamp to the average current through the lamp substantially constant.

In U.S. Pat. Nos. 6,411,064 and 6,417,649 for G. D. Brink pulsers for cardiac defibrillation are described that are used for producing electric shocks to arrest the chaotic cardiac contractions that occur during ventricular fibrillation, and to restore a normal cardiac rhythm. To administer such an electrical shock to the heart, defibrillator pads are placed on the person's chest, and an electric pulse of a proper magnitude and shape is administered to the victim through the pads. The characteristic parameters of electric impulse are a pulse amplitude of 6 kV, the accumulated energy per discharge is 240 J and the duty cycle is 0.5-4%.

In the published European patent application No. 1052051 for J. O. Reynolds an arc welding machine and a welding power supply for pulsed spray welding are disclosed. The characteristic electric pulses parameters are a peak pulsed power more than 10 kW, a duty cycle of about 5-6%, and a pulse duration of 1.71 ms. The arc welding machine is designed for providing a continuous feed electrode to a weld site, and includes a line frequency transformer having a primary winding, a first secondary winding, and a second secondary winding. The first secondary winding provides a welding power having a first voltage at a welding power output terminal. The second secondary winding provides a second welding power hawing a second higher voltage at an input terminal of a switch, the switch being controlled to provide a pulsed power at the welding power output terminal. The arc welding machine produces a pulsed power having a fixed pulse width and a fixed frequency.

B. A. Tozer in “Rotating plasma”, Proc. IEEE, Vol. 112, No. 1, January 1965, and later B. Lehnert in the review “Rotating Plasmas”, Nuclear Fusion 11, 1971, pp. 485-533, have described various discharge units utilizing external magnetic field and pulsers based on capacitors as energy accumulators. The systems described are designed for plasma production and plasma investigation. A pulser generating single pulses includes mainly a capacitor that through an ignitron acting as a switch and limiting resistors is connected to the electrodes of the discharge unit which is a plasma device. The system pulser-discharge unit can be put into a free-wheeling mode when the energy accumulating capacitor and the discharge unit are cut off by short connecting a capacitor by another ignitron. Finally the angular momentum of the plasma can be recovered by applying a short-circuit across the electrodes of the discharge unit provided that the circuit resistance is kept sufficiently small. The pulsed power characteristic for such experiments is of the magnitude of order of 1-100 MW, and the voltages can range up to tenths of kilovolts and the current up to tenths of kiloamperes. The characteristic pulse time is 0.1-1 ms.

In the cited article for D. V. Mozgrin a pulser for producing discharges between an anode and a magnetron-sputtering cathode is described. The system comprising pulser and discharge unit was used for plasma investigation and thin metal film deposition. The pulser included a long line, a switch and matching unit. The capacitance of the long line acting as an energy accumulator forms a substantially rectangular current pulse in the load. The accumulated energy was 5.5 kJ. The pulser is characterized by following electric parameters: pulse duration 1.5 ms, a pulse repetition frequency of 10 Hz, a duty cycle of 1.5%, the no-load voltage ranging to as much as 2.4 kV and a short-circuit current amplitude of up to 3 kA.

In B. M. DeKoven et al., “Carbon Thin Film Deposition Using High Power Pulsed Magnetron Sputtering”, 46^{th} Annual Technical Conference Proceedings, 2003, ISSN 0737-5921, 2003, Soc. of Vac. Coaters, a pulser for producing discharges between an anode and a magnetron sputtering cathode is described. The system was used for plasma production and deposition of thin carbon films. The energy accumulator was a capacitor. The pulse parameters were: the pulse shape was about sinusoid-shaped, the pulse width was 60-120 μs, the pulse repetition or pulsing frequency was 10-200 Hz, the duty cycle was 1.4%, the capacitor charging voltage was 500-2000 V, the load current up to 350 A, the peak pulsed power was up to one megawatt, and the average power up to 5 kW.

In U.S. Pat. No. 6,296,742 and in V. Kouznetsov et al., “A novel pulsed magnetron sputter technique utilizing very high target power densities”, Surface and Coating Techn. 122, 1999, pp. 290-293, a pulser having a capacitor as energy accumulator is described. The capacitor is charged from a charging power supply and is discharged over the discharge unit through an inductance or inductor limiting the peak current as controlled by a switch. The charging power supply comprises a first transformer connected on its primary side to a mains power supply and connected on its secondary side to the capacitor, and a diode is connected in one of the lines from the secondary side to the capacitor. The switch is controlled to adopt a conducting stage by an alternating voltage having a substantially 180° offset in relation to an alternating current obtained from the power supply. A second transformer is connected on its primary side to the same mains supply as the first transformer and gives on its secondary side a voltage substantially 180° offset in relation to an alternating current obtained on the secondary side of the first transformer, this offset voltage controlling the switch to start and end the discharge of the capacitor. The pulser disclosed in the patent is suitable for providing discharges in the discharge unit with a duty cycle of (10⁻⁵-10)%. The pulser described in the article is capable of delivering pulses having a peak power of up to 2.4 MW, a pulse amplitude of 2000 V and a current of 1200 A, at a repetition frequency of 50 Hz and a pulse width in the range of 50-100 μs for a duty cycle of 0.25-0.5%.

All the methods and apparatus described above are based on a capacitor serving as the energy accumulator. Hence, the energy is stored as the energy of an electric field. Other methods exist for storing energy such as using an inductance. In that case the energy is stored as the energy of a magnetic field. Usually this method is related to heavy-current pulsed power engineering and can be used for electron acceleration in pulsed electrons accelerators, in powerful pulsed lasers, in pulsed X-ray and neutrons sources. In Russian patent No. 2194326 for O. G. Egorov a method for energy extraction from an inductive energy accumulator and its transmission to a load is described. This method is used for transmitting energy of about 10⁷-10⁸ J for a time of about 300-500 ns to a load. The method involves that a current passes inductive energy accumulators connected in series for a time period of 0.5-1.0 s. As soon as the desired value of the current in the accumulators has been attained, the accumulators are sequentially connected to the load. Possible arc discharges between the electrodes are suppressed by passing a counter-current-pulse between them. The duration of the counter-current pulse is not shorter than the time required for recovering the full electric field strength over the electrode gap, i.e. the plasma decay time. The duty cycle is as a maximum (3-5)·10⁻⁵%. The pulsed peak power is up to the gigawatt range.

All examples of low duty cycle powerful pulsers described above are based on LC, LR, RC circuits, where C is capacitance, L is inductance, and R is resistance, and generate half-period sinusoidal pulses or pulses having an exponential decay of the current from a peak value. Modern technology, in particular technology based on powerful discharges between an anode and a magnetron-sputtering cathode, requires development of programmable pulsers producing pulses having a peak power from the kilowatt range up to the megawatt range and generating pulses having a substantially rectangular shape or pulses having two power levels, or operating in a continuous regime. The pulse duration should be variable in the range of tenths of microseconds to hundreds of milliseconds. The duty cycle should be variable in at least the range of (10⁻⁵-0.5)%. The transition time from one to another operational mode should be in the range of a few microseconds.

One actual problem arising in low duty cycle pulsing is the problem of igniting a discharge in a discharge unit. Different authors describe different methods and apparatus to solve this problem, see the cited U.S. patent applications Nos. 2003/0057875 and 2002/0149326, U.S. patent application No. 2002/0043336, U.S. Pat. No. 6,413,382, and the cited article for D. V. Mozgrin et al. An effective solution has not yet been disclosed.

Another actual problem arising in low duty cycle pulsing in a discharge unit comprising an anode and a magnetron sputtering cathode is the problem associated with suppression of non-thermal and thermal arc discharges. The phenomenon of a high voltage magnetron discharge continuing into an arc discharge depends on many factors, see the published International patent application No. WO 02/103078, the cited article by D. V. Mozgrin et al., I. K. Fetisov et al., “Impulse irradiation plasma technology for film deposition”, Vacuum, Vol. 53, 1999, pp. 133-136, J. Sellers, “Asymmetric bipolar pulsed DC: the enabling technology for reactive PVD”, Surface and Coating Techn., Vol. 98, 1998, pp. 1245-1250. There are published methods, see U.S. Pat. No. 5,584,974 and the published European patent application No. 1298770, of arc suppression schemes incorporated in pulsers but still an efficient solution for low duty cycle powerful pulses has not yet been disclosed.

The particular technical field of pulsed powerful discharges in crossed electric and magnetic fields, so called E X B discharges, was intensively investigated during the years 1958-1984. The crossed field technique was used for basic research of fully ionized, dense plasmas in laboratories and for modeling cosmic plasmas. The main proposed applications were controlled thermonuclear fusion, isotope separation, electric energy accumulators for electric power engineering purposes, and plasma guns for vehicle propulsion systems. The results of the basic investigations and applications of such crossed fields discharges and the methods used for producing and using them are in detail described in the cited papers by B. A. Tozer and B. Lehnert.

The most common parameters used for E X B discharges between an anode and a cathode were as follows. The voltage over the anode-cathode discharge gap ranged from hundreds of volts up to two kilovolts, the discharge-driving current ranged from hundreds of amperes up to a few kiloamperes, and the peak power of the pulsed discharges had values up to the megawatt range. The discharge time varied from tens of microseconds up to milliseconds. The characteristic plasma density was from 10¹⁹ m⁻³ to 10²¹ m⁻³. The power supplies were based on capacitors discharged through an inductance over the discharge unit comprising an anode and a cathode, a magnetic field applied at the surface of the cathode.

After the years 1995-1999 pulsed powerful E X B discharges were again studied when it was suggested to use this kind of electric discharges in systems comprising an anode and a magnetron sputtering cathode. Then, the main goal was the production of dense plasmas of gases and solids and plasmas to be used in the technical areas of vacuum technology, work piece etching, and thin film deposition. The term “a plasma of solids” means herein a plasma produced by ionizing a vapor of solid materials that in turn can be produced by e.g. PVD (Physical Vapor Deposition).

This new special technical field can be termed High Power Pulsed Magnetron Sputtering (HPPMS). According to data published for this field the anode-cathode voltage may be as much as few hundreds of volts up to 1-2 kV, the discharge driving current up to ten kiloamperes, and the peak power of the discharge pulses as much as tenths of a kilowatt up to the megawatt range. The discharge time is from tens of microseconds up to ten milliseconds. Such parameters of electric discharges allow generating a plasma having a density of 10¹⁹-10²¹ m⁻³ near the cathode and an electron temperature of about 3-20 eV. The composition of the plasma near the cathode is such that the metal plasma portion is up to 30% or even higher of the gas plasma and the degree of metal vapor ionization up to 70% or higher. The deposition rate of the cathode material is about 80 μm/min. It can be observed that the parameters of E X B discharges and plasmas as used in the previous period and now are similar. The characteristic dimension of devices used in fusion experiments is tens of centimeters up to a few meters and the magnetic field strength is in the range of 0.1-4 T. The corresponding parameters devices used for HPPMS are about tens of centimeters and 0.03-0.2 T. It results, for light elements, such as H and N, in almost the same magnitude of the ratio a=rᵢ/D where rᵢ is the ion Larmor radius and D is the characteristic device dimension. For all devices rᵢ<<D. It means that the knowledge accumulated earlier can be used for interpretation of results obtained in HPPMS.

Available results for HPPMS have been obtained using different magnetron sputtering cathodes operated in different regimes. A main problem includes the lack of a “reference magnetron unit” and a “reference sputtering-deposition process”. It complicates comparison of obtained results and scaling of operating regimes and experimental devices.

After the time when HPPMS was initially described a number of investigations have shown that HPPMS allows generating a mixture of gas/metal plasmas having densities of up to about 10²¹ m⁻³. The degree of metal vapor ionization is up to 70%. The deposition rates of cathode material for the pulsed discharges are about 80 μm/min. These extreme plasma parameters suggest a broad potential for applications of HPPMS.

Powerful discharges between the anode and the magnetron sputtering cathode produce a number of earlier unknown phenomena that much complicate development of high intensity plasma sources. The most important ones can include:

the existence of two different modes, called high and low voltage diffused discharges, between an anode and a magnetron sputtering cathode,

a sharp decrease of the deposition rate for higher discharge currents,

a burn-out current phenomenon earlier described in fusion experiments,

the generation of electrons having energies up to 1.3 keV, and

plasma, or floating, potential oscillations having frequencies of about 0.1-10 MHz.

Available experimental data indicate that an industrial plasma source should be based on two main principles:

a specific topology and topography of the magnetic field in the vicinity of and in areas remote of the magnetron cathode, and

a combination of low and high voltage diffused discharges between the anode and the magnetron cathode.

Specific, important features of HPPMS include

formation of layers of sputtering gas at the surfaces of the electrodes,

a significant amount of energy injected in the discharge gap during each pulse, and

the existence of said two different kinds of discharges, the high and low voltage diffused discharges.

An analysis of these specific features allows a determination of suitable values of the parameters of the sputtering pulses.

Moreover, even very small impurities of sputtering and reactive gases have a strong negative effect on the quality of films deposited using e.g. PVD. Such impurities can come from the sputtering and reactive gases but usually the gases used in thin film technology are very clean. It is more probable that pollution of plasmas produced by high current discharges in gas and vapor located between the anode and the magnetron sputtering cathode is derived from gases adsorbed by the exposed surfaces of the electrodes and the internal wall surfaces of the discharge chamber, also called the process chamber. It appears that the originally clean surfaces formed from the atoms of the bulk materials building the electrodes and the walls of the process chamber are almost always covered with adsorbed gas atoms. The atoms of gases colliding with the surfaces diffuse below the surfaces with a high probability that is in the range 0.3-0.5 up to the time when four atoms of the solid at the surface surround one gas atom, up to the time when the proportion between adsorbed gas atoms and solids atoms at the surface of the solid material is 1:4. For such a proportion between adsorbed gas atoms and atoms of the solid at the surface the binding energy of gas atoms to atoms of the solid at the surface is lowest and is about 2-4 eV per adsorbed gas atom. Up to some extent such a coating of gas atoms can be denoted as a monolayer. The monolayer can typically consist of about 4·10¹⁸ m⁻² gas atoms.

The adsorption very much depends on the chemical and physical properties of the gases. In particular, noble gases are, because of polarization, adsorbed at surfaces having ambient temperature to form up to two monolayers. Reactive gases can be adsorbed at the chemically inert surfaces to form up to many monolayers. The monolayers are very quickly formed at the solid surfaces, see D. J. Rose and M. Clark, Jr., “Plasma and Controlled Fusion”, published jointly by the M. I. T. Press, Massachusetts Institute of Technology and John Wiley & Sons, New York-London, 1960, second printing 1965, section 3.7, pp. 43-45. The characteristic number of arriving gas atoms having room temperature for a pressure of one mTorr is about 4·10²¹ 1/m²s. It means that the first monolayer will be formed during a time period of about one millisecond. The characteristic time between pulses used in low duty cycle high current magnetron sputtering is about 10-20 milliseconds. One can see that during the time intervals between pulses many monolayers can be formed at the surfaces of the electrodes and the process chamber. Motionless surfaces of electrodes and process chamber can thus be considered similar to potential, large injectors of gases into the process chamber. These injectors are operating in the “pulsed regime” during the pulsed electric discharges. As an example one can take the process of desorption of gases from the cathode surface due to its bombardment by energetic ions coming from the potential separation zone located near the cathode. The characteristic energy of the arriving ions is about several hundreds of electronvolts. It is enough to “sputter away” the gas atoms adsorbed between the discharge pulses. As an example a 150 mm circular magnetron-sputtering cathode can be considered. The cathode surface is 1.8·10⁻² m². It means that for five monolayers the total number of adsorbed atoms is about 3.6·10¹⁷ atoms. During the discharge pulses these atoms are sputtered away from the cathode and arrive in the process chamber. It has been found that the sputtering time is about 100 microseconds. If the pulse time, i.e. the length of each pulse, is about 100 microseconds the sputtering process will preferably only comprise the sputtering of gas atoms adsorbed between each pulse. Hence, one way to increase the sputtering rate of the target material as well as to achieve controllable gas parameters in the process chamber would be to use longer pulses, e.g. pulser longer than 100 microseconds. However, an analysis of physical and technical aspects shows that pulses having lengths in the range of 1-100 milliseconds are most optimal.

As indicated above, it has been found that there are two kinds of stationary discharges between the anode and the magnetron sputtering cathode, called high and low voltage diffused discharges. The high voltage diffused discharges have a characteristic anode-cathode voltage drop of 200-2000 V. The low voltage diffused discharges have an anode-cathode voltage drop of about a few tenths of volts. The high voltage diffused discharges are characterized by intensive cathode sputtering but a relatively low gas and vapor ionization efficiency. On the contrary, the low voltage diffused discharges result in an almost zero sputtering efficiency but they have a high gas and vapor ionization efficiency. The transition of one kind of these discharges into one of the other kind is produced by increasing the discharge current. However, the important parameter is the magnetic field strength at the magnetron cathode sputtering surface. A transition from a high voltage discharge to a low voltage discharge is obtained if the lateral magnetic field strength has a maximum value at the cathode surface in the range of 0.05-0.25 T. The transition current depends on the cathode area and is in the range 30 A-3 kA. The typical discharge current of a low voltage diffused discharge is in the range of 1-10 kA.

The conventional method used for generating the driving electric pulses for achieving high current, low duty cycle magnetron sputtering includes discharging a charged capacitor through a current limiting inductance over the discharge unit including the anode and the magnetron sputtering cathode. For the parameters of discharges described above the characteristic energy accumulated in such a discharge capacitor is up to 200-300 kJ. This kind of capacitors have been used for high current E X B discharges for thermonuclear experiments and are assembled from a multitude of small capacitor banks connected in parallel to each other. Such capacitor batteries have large dimensions, a complex design, and a complex service, this not being acceptable for industrial use. Another problem arising in low duty cycle high current magnetron discharges is the relatively high probability of transition of the high and low voltage diffused discharges into arc discharges. Arc discharges for parameters of 300 kJ accumulated energy and 10 kA discharge current result in serious damage to discharge electrodes and work pieces as well as in production of liquid droplets of the target material. In the conventional technology this parasitic effect is usually eliminated by special arc suppression schemes. Devices required for arc suppression schemes are extremely expensive and complex for high energy pulses such as if the energy accumulated in the capacitor battery is 300 kJ and the discharge current is 10 kA. Moreover, methods for arc suppression used in practice now for small cathodes are generally not acceptable for large surface industrial cathodes used for mass production or mass processing of work pieces.

### SUMMARY

It is an object of present invention to provide methods and apparatus allowing the production of relatively long current pulses for driving discharges over a discharge gap, in particular pulses having also a relatively large energy content.

It is another object of present invention to provide methods and apparatus allowing the production of current pulses having an arbitrary shape for driving discharges over a discharge gap.

It is another object of present invention to provide methods and apparatus allowing the production of powerful and very powerful current pulses for driving discharges, the methods and apparatus not requiring use of very large capacitors or capacitor assemblies.

It is another object of present invention to provide methods and apparatus allowing that high and variable sputter/deposition rates are achieved in a magnetron sputtering device.

It is another object of present invention to provide methods and apparatus allowing that high and variable target vapor ionization rates are achieved in a magnetron sputtering device.

It is another object of present invention to provide a method for operating a magnetron sputtering device and a magnetron sputtering device allowing relatively high and variable sputtering/deposition rates and/or relatively high and variable target vapor ionization rates.

A problem, which the invention intends to solve, is thus how to generate relatively long current pulses such as long rectangular pulses, in particular current pulses that also have large energy content, for driving discharges over a discharge gap. A specific problem is how to generate such pulses and also how to give them an arbitrary shape for driving discharges in a magnetron sputtering device.

Another problem, which the invention intends to solve, is how to generate powerful and very powerful current pulses using only capacitors or capacitor assemblies of moderate or standard sizes, not requiring that all the power needed for driving a discharges is contained in a single capacitor or capacitor assembly.

The methods as disclosed herein are based on generating relatively long pulses of high current intensities by summing shorter current pulses, called herein also element current pulses, that can have equal or variable amplitudes or heights. The corresponding apparatus is based on operating power supplies for producing such shorter current pulses and summing them to each other to produce the relatively long pulses of high intensity or amplitude. E.g. the sum of single polarity, half period sinusoidal currents shifted in time at 120° and following one after another gives an almost constant current. The deviation of amplitude is about ±6% of the average value. The pulses resulting from the element pulses are herein called composite pulses or resulting pulses.

This means, that e.g. for driving a single discharge using a current pulse, this current pulse is a composed pulse or a composite pulse that, e.g. for a sufficiently long composite pulse, can obtain driving energy at least twice from the same pulser, the pulser being charged during the composite pulse, between the at least two times when the pulser is discharged to form the composite pulse.

The methods and apparatus as disclosed herein particularly relate to the HPPMS field and preferably the second principle mentioned above, i.e. combining low and high voltage diffused discharges between the anode and the magnetron cathode in a magnetron sputtering device to achieve high and variable sputtering/deposition rates and high and variable target vapor ionization rates. The methods and apparatus as disclosed herein allow the use of industrial magnetron sputtering cathodes having large surfaces and operated with pulses having low to relatively high duty cycles and relatively high discharge currents.

The method of producing pulses as described herein allows that in a load a current varying in time according to any function is obtained. Also, for e.g. magnetron sputtering this method gives a unique method of arc suppression, because if arcing occurs the next element current pulse will not start. It means that the energy that will be injected in the discharge electrodes is not more than the energy of typically 1-2 element pulses. In a characteristic example for a magnetron of large area the method can give about 0.1-1 J for a peak power of 5 MW of the pulsed discharges. Such an energy of about 0.1-1 J does not result in any noticeable destruction of electrodes and in any noticeable appearance of droplets. The practical design of a corresponding pulse generator can include simply combining simple pulse driving circuits, called herein element pulse supplies or element pulsers, by connecting them in parallel to the same anode-cathode unit, also called discharge unit, each circuit including a capacitor, an inductor and a switch that can be solid state switch or semiconductor switch such as a thyristor or an IGBT module. The system can be controlled by a suitable control unit such as by a PC having adapted software.

Generally thus, for producing discharges, element electric pulses are provided from a plurality of different electric pulse sources, in particular three or more electric pulse sources, the pulses controlled by a control and monitoring unit. The element electric pulses are summed, such as by connecting the pulse sources in parallel, to form resulting electric pulses. In a first aspect, each of the resulting electric pulses has at least partly a substantially constant level or has a portion that is substantially constant and then the substantially constant level is formed from at least two element electric pulses having the same pulse height or pulse amplitude. The resulting electric pulses are applied to electrodes. In a second aspect, the element electric pulses are produced to all have the same polarity and also substantially the shape of half a period of a sinusoid of a single frequency or of the same period time and then the time intervals between starts of sequential element electric pulses are relatively short, not being not larger than one third of the period of the sinusoid. In a third aspect the element electric pulses are provided from three or more electric pulse sources that operate substantially independently of each other. In a fourth aspect the element electric pulses are summed to form resulting electric pulses having substantially a triangle shape. Thus, for producing e.g. a pulse having a sloping start portion, the element pulses are successively given increased amplitudes, at least two element pulses then required to form such a sloping portion. In a fifth aspect, energy from the same pulser is used to form a resulting pulse at least twice during a single resulting pulse.

The shapes, in particular the peak levels or amplitudes, the starts and/or the ends, of the element electric pulses are can be controlled to produce, when summed, to produce resulting electric pulses having a desired shape and desired start/end times. The element electric pulses have preferably all the same polarity. For sinusoid element pulses, the time interval between starts of sequential element electric pulses is preferably smaller than ½ of a sinusoid period, or even smaller than 0.4 of a sinusoid period and preferably not larger than one third of a sinusoid period. Thus, the time interval between starts of sequential element electric pulses can be in the range of ⅙-½ or 0.28-0.4 of a sinusoid period, such as substantially equal to one third of a sinusoid period.

Preferably, the element electric pulses are provided by discharging elements capable of storing electric energy such as capacitors or inductors, in particular by discharging capacitors through inductors, the discharging circuits then being or acting like harmonic oscillators. Then, before discharging such capacitors, they can be charged to controlled, adapted voltages in order to give, when discharged, element pulses having adapted amplitudes.

In magnetron sputtering a sputtering gas and possibly reactive gases and a work piece are provided to/in a processing chamber, driving electric pulses are produced, each of those pulses having at least partly a substantially constant level according to the first aspect, and the driving electric pulses are applied to create discharges in the processing chamber between an anode and a magnetron sputtering cathode. The driving electric pulses are obtained by summing element electric pulses generated by a plurality of electric pulse sources, and in the first aspect, the substantially constant level is formed from at least two element electric pulses having the same pulse height or pulse amplitude that are successively or consecutively applied. It appears, that for magnetron sputtering the element electric pulses are provided as current pulses and then they typically have an amplitude or pulse height that is not larger than 10 kA.

A plurality of sequential or consecutive element electric pulses can have amplitudes or pulse heights varying in the time as a single step square function or a rectangular function, or as a two step square function to form resulting pulses having the corresponding shape. They can also have amplitudes or pulse heights varying in the time as a two step square function, so that consecutive ones of said two step square functions follow directly after each other with no gap, for at least a repeated number of said two step square functions.

### BRIEF DESCRIPTION OF THE DRAWINGS

The invention will now be described by way of a non-limiting embodiment with reference to the accompanying drawings, in which:

FIG. 1a is a diagram showing three single polarity, half period sinusoidal pulses shifted in time more than half a period, i.e. more than 180°,

FIG. 1b is a diagram showing three single polarity, half period sinusoidal pulses shifted in time by 120°,

FIG. 1c is a diagram showing the sum of three single polarity, half period sinusoidal pulses shifted in time by 120°,

FIG. 1d is a diagram showing the sum of seven single polarity, half period sinusoidal pulses shifted in time by 120°,

FIG. 2 is a diagram showing the sum of single polarity, half period sinusoidal pulses, the amplitudes of the pulses modulated by a periodical one step square function,

FIG. 3 is a diagram showing the sum of single polarity, half period sinusoidal pulses, the amplitudes of the pulses modulated by a periodical two step square function,

FIG. 4 is a diagram showing the sum of single polarity, half period sinusoidal pulses, the amplitudes of the pulses modulated by a square function,

FIG. 5 is a diagram showing the sum of single polarity, half period sinusoidal pulses, the amplitudes of the pulses modulated by a linear or triangular function,

FIG. 6 is a diagram showing schematically a pulse including high level, periodic shorter pulses superposed on a lower level pulse of the full pulse length,

FIG. 7 is a diagram showing schematically a sequence of pulses of the kind illustrated in FIG. 6,

FIG. 8 is a diagram showing schematically a current shape for driving a discharge including a DC current of a lower level on which bursts of periodic pulses of a higher level are periodically superposed,

FIG. 9 is a block diagram of device for generating discharges by summing elementary pulses,

FIG. 10a is a circuit diagram of a pulser generating single polarity, half period sinusoidal pulses,

FIG. 10b is a circuit diagram of a pulser assembly including three pulsers of the kind illustrated in FIG. 10a and connected to the same discharge gap,

FIG. 10c is a circuit diagram similar to FIG. 10b illustrating control of the energy content of delivered pulses, and

FIG. 11 is a schematic view of a device for magnetically enhanced sputtering,

### DETAILED DESCRIPTION

Methods and apparatus will now be described for generating relatively long electrical pulses applied between discharge electrodes, in particular relatively powerful pulses. The description will be made for the specific technical field of pulsed, high current magnetron sputtering but it is obvious to anyone skilled in the art that the methods and apparatus as described can be applied to any technical field where such pulses are used for producing electrical discharges.

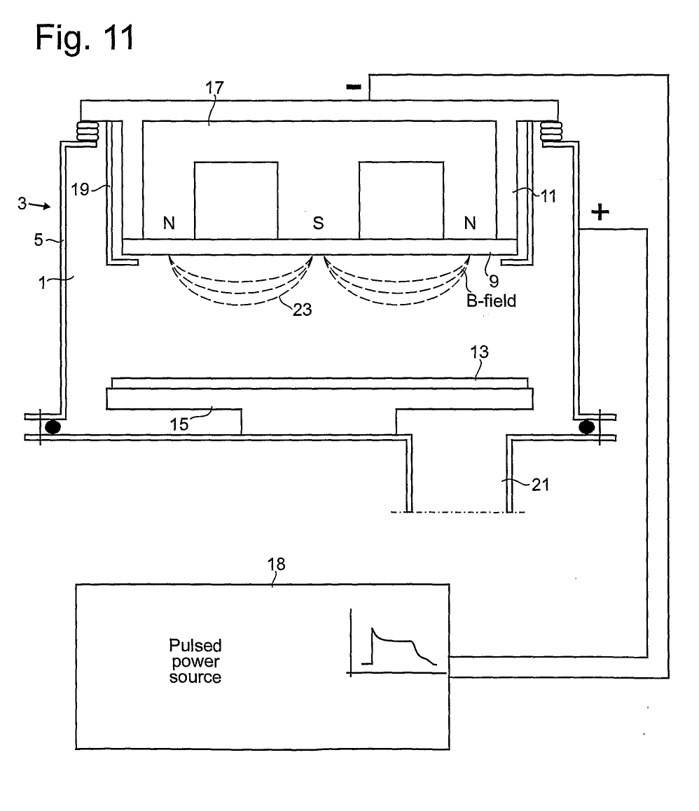

In FIG. 11 a substantially conventional magnetron sputtering device is schematically shown. A sputtering chamber 1 is formed in the interior of a housing 3 having walls 5 made of e.g. stainless steel plate, the walls of the housing thus being electrically conducting, and the housing having the shape of circular cylinder. The target 9 is located in parallel to the flat end walls of the cylinder and is carried by a support 11 made of some electrically conducting material. The target 9 is a circular plate of the material, which is to be applied to some object, called substrate or work-piece, possibly after reacting with some gas, and the support 11 has an annular, flat circular surface, to which the target is attached. The target 9 is located more adjacent to one of the flat end walls of the cylindrical housing 3, and the substrate 13, which is to be coated, is located at the opposite end wall. The substrate 13 can e.g. be plate-shaped and is attached to a support 15 at that end wall.

At the rear side of the target 9, at that surface which is not directed towards the center of the chamber 1, a magnet assembly 17 is mounted so that the north pole or poles are arranged at the periphery of the target and the south pole or poles at the center of the support 11 and the target 9. Thus, the magnetic field lines 23 of the magnets 17 pass from the periphery of the support 11 to the center thereof. The magnetic field B is most intense at the poles of the magnets 17. The electric system of the sputtering device includes electrodes between which a voltage from a power supply 18 is applied for ionizing the gas in the chamber 1. In the illustrated embodiment, the anode is formed by the electrically conducting walls 5 of the housing 3, which e.g. can be grounded, but alternatively e.g. a separate anode, not shown, can be used. The cathode is formed by the target 9 and is negatively biased in relation to the anode. The substrate 13 can have some suitable electric potential. The support 11 has its sides protected by shields 19. A gas inlet for gases to be ionized such as argon and possibly reactive gases is indicated at 21.

Characteristic parameters in producing magnetron sputtering discharges can be as follows. The anode-cathode discharge voltage varies for all target materials from about 200 V up to 2000 V but for most industrial operating regimes of interest the discharge voltage is about 200-500 V. The characteristic current density is of the order of magnitude of 0.5 A -20 A, e.g. about 10 A/cm². It means that for a magnetron sputtering cathode having an exposed, active area of 1000 cm² the discharge current is about 10 kA. It has been found that for low duty cycle, high current magnetron discharges the equivalent impedance of the anode-cathode discharge gap is the same electric resistance both for high and low voltage, high current discharges. It has been found that this electric resistance R of the anode-cathode gap is about 0.02-0.05 Ohm. The characteristic reactive impedance ρ=(L/C)^{1/2} of LC circuits as used for low duty cycle; high current magnetron discharges is about a few Ohms.

According to electromagnetic theory for series circuits the time variation of the current in such circuits and the voltage over the resistive component is periodic and also decaying if the relation R<2ρ is fulfilled. It means that in low duty cycle sputtering the gap resistance R has to be smaller than 2ρ, which is about few Ohms, to obtain that the discharge will be driven by such a periodic and decaying current. Actually, R is about 0.02-0.05 Ohm. In other words, if series circuits are used for such kinds of electric discharge production, the relation R<ρ, and even R<<ρ, is valid and the discharge has a periodic, sinusoidal character that is also decaying. The decay time depends on the circuit quality factor that is ρ/R and for these discharges it is about 50. For such quality factors the characteristic decay time is about three periods of oscillations. Therefore the half period oscillations are almost identical to sinusoids.

Also, by Laplace analysis it has been found that if the reactive part of the impedance of the discharge circuits is much higher than the active part, i.e. the resistive part, of the impedance, the electrical processes in two or more discharge circuits connected to the same load, i.e. the same anode-cathode gap, are almost independent of each other. It means that the current in the load substantially is the sum of the currents of the discharge circuits connected the load and that the current in the load as generated by each of the discharge circuits is almost a sinusoid current, rising from a zero value at the time of the start of the respective discharge of the capacitor. In such a current only the first portion corresponding to a half-period of the approximately sinusoidal waveform can be used in producing a discharge over the anode-cathode gap.

It is e.g. a well known fact that the sum of electrical currents containing only the half periods of sinusoidal currents having always the same polarity and shifted by 120° in time and following one after another, is an almost constant electrical current. The deviation of the resulting summed current from its average value is about ±6%.

By driving the discharges of a magnetron sputtering process by such a resulting current being the sum obtained from a plurality of identical discharge circuits acting in a way similar to that of harmonic oscillators, generally from a plurality of element pulsed power supplies of conventional design, is achieved that in the load a current varying in the time according to any function can be obtained, by only controlling the discharge times and the initial discharge voltages of the element power supplies, in particular the voltage to which the respective capacitor has been or is being charged. Also, such a procedure of producing the required discharges provides a unique method of arc suppression, because if arcing occurs the next element pulsed power supply will not be discharged or will not produce any pulse for driving the discharge over the anode-cathode gap. It means that in such cases the energy that will be injected in the discharge electrodes will typically correspond to not more than the energy of 1-2 element discharge pulses.

In e.g. a large magnetron, energy of about 0.1-1 J or even up to 10 J may be consumed in each discharge for a peak power of 5 MW of the discharge pulses without any noticeable destruction of electrodes and appearance of droplets of sputtered material. As will be described in more detail hereinafter, the practical design of a corresponding pulse generator or power supply assembly can include that circuits operating with the same anode-cathode unit are simply combined to form a pulsed power supply assembly so that each circuit is connected in parallel to the anode-cathode gap or discharge gap, each circuit including a capacitor, an inductance, a solid state switch, that can be a thyristor or an IGBT module that also acts as a diode or rectifier. Thus, in the circuit there must generally be a switch function and a rectifying function. The system can be controlled by a conventional processor or computer running adapted software.

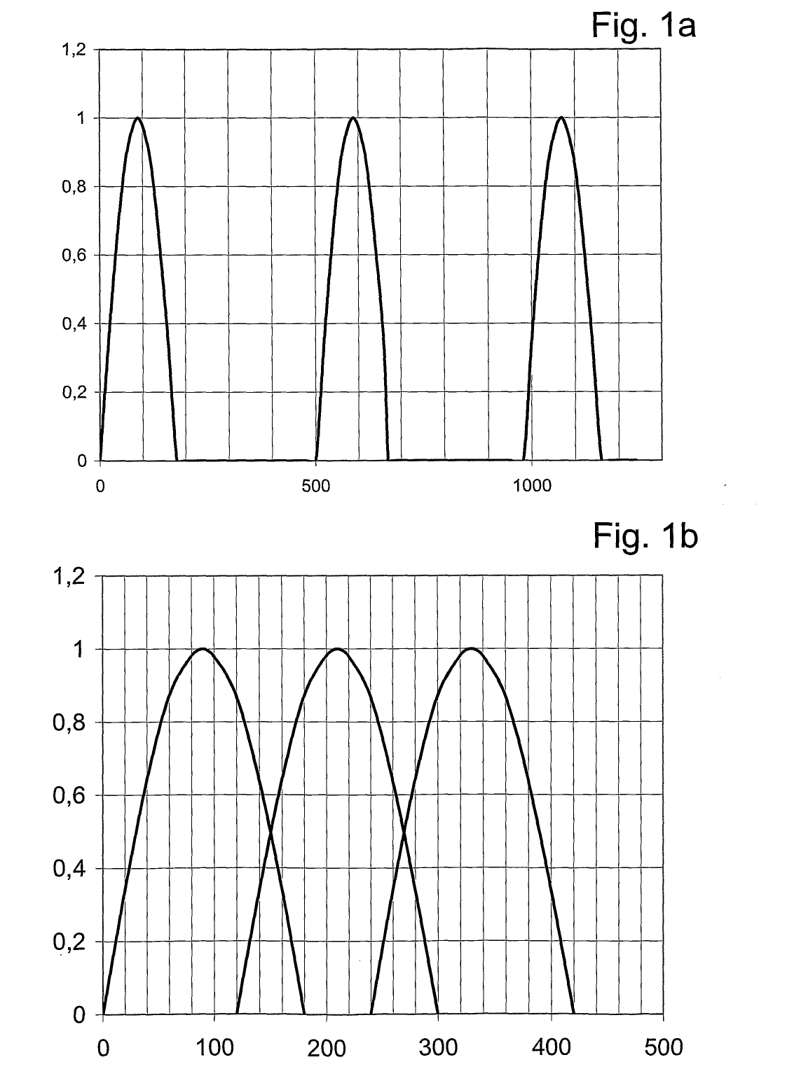

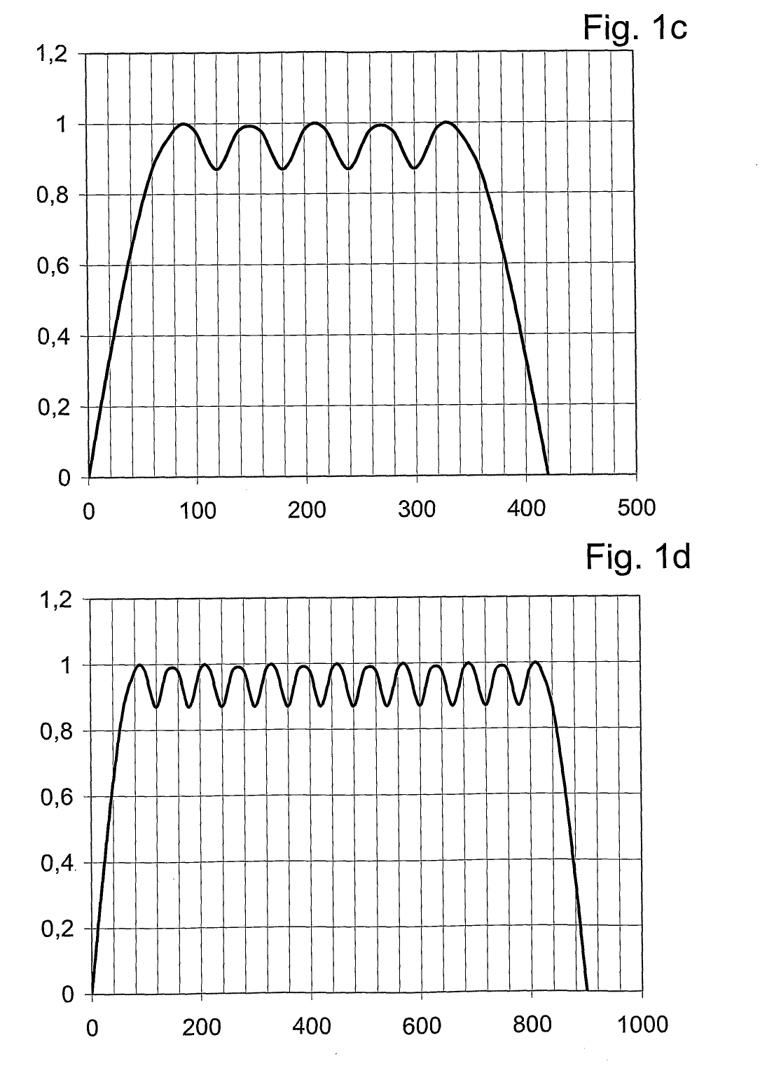

The method of summing short pulses or pulses each having a relatively low energy is demonstrated by the graphs of FIGS. 1a-d. In the diagram of FIG. 1a three half period sinusoidal pulses are shown, i.e. pulses obtained by rectifying full sinusoidal waves, that are shifted in time for more than half a period. In this case there is no effect of summing the pulses. In FIG. 1b three similar pulses are shown that are shifted by one third of a full period, i.e. by 120°. The sum of these pulses is shown in FIG. 1c. In FIG. 1d the sum of seven pulses shifted by one third of half a full period, i.e. by 120° is shown. Hence, it is obvious that by summing short, element pulses it is possible to get any kind of resulting, integral pulse as well as a continuous regime, i.e. a DC level being constant or having any desired shape in time. In the case of summing identical half period sinusoidal pulses shifted by 120° the oscillations of the resulting amplitude is about ±6%.

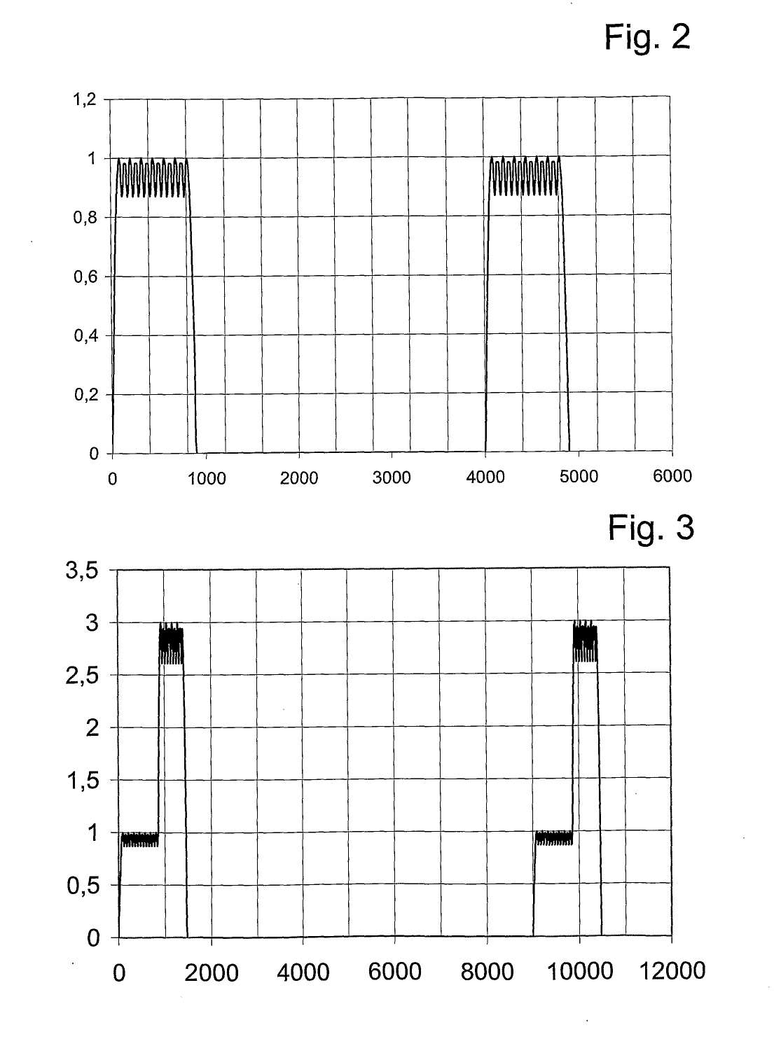

For plasma surface engineering different discharges between the anode and the magnetron sputtering cathode are used. In particular they include DC, medium frequency pulsed, low duty cycle high current pulsed discharges and different combination thereof. If possible, these different discharges should be produced in the same coating machine using a single power supply. The principle of summing short half period sinusoidal pulses can be used to allow it. In FIGS. 2-8 examples of these regimes are shown. As has been mentioned above, it has been found using Laplace analysis that the processes in different oscillators connected to the same load are independent if the ratio L/C is much higher than R, where L is the inductance of the oscillator, C is the capacitance of the oscillator and R is the resistance of the load.

FIG. 2 is a graph of the sum of a plurality of half period sinusoidal pulses of a single polarity forming a resulting sequence of periodical, substantially rectangular identical pulses. This type of pulses is the type basically used for the method of magnetron sputtering that is described in the cited U.S. Pat. No. 6,296,742. According to that patent the discharge current between the anode and the magnetron sputtering cathode is as high as necessary to achieve the area of powerful discharges in crossed fields, i.e. of E X B discharges. The main requirement in this case is the substantially rectangular shape of the current pulse in order to maintain the discharge during all time in the area of E X B discharges. It has been found that oscillations of the driving discharge current within a range of ±6% do not result in a transition of the discharge into another kind, such as into a glow discharge or an arc discharge. Therefore, the pulse summing method as described herein is suitable for the method of magnetically enhanced sputtering described in the cited U.S. Pat. No. 6,296,742. Using the pulsed power supply described in said patent for generating the current in the load, the area of powerful E X B discharges is reached only for very short time periods, since for most of the time the discharges are actually in the range of normal glow discharges.

The combination of different element pulses for generating discharges in the way indicated above can be used to obtain high sputtering/deposition rates and/or a high reactivity of reactive processes, such as for depositing nitride and oxide films with a low consumption of the reactive gases such as nitrogen and oxygen. The main kinds of discharges that can be used include normal glow discharges, abnormal glow discharges, low voltage high current diffused discharges, and powerful high current E X B discharges according to the cited U.S. Pat. No. 6,296,742 and their combinations, following sequentially in time.

The high current rectangular pulses that according to FIG. 2 can be obtained by combining half-period or single polarity sinusoidal signals can be used for achieving low voltage high current diffused discharges if the lateral component of magnetron magnetic field strength at the exposed cathode surface is in the range of 0.05-0.25 T. The transition from a high voltage discharge to a low voltage discharge depends on the intensity or height of the discharge current. It was found that the transition current amplitude of a rectangular pulse is in the range 100-200 A dependent on the material of the magnetron sputtering cathode. It was found that the low voltage discharges are diffused across of all over the cathode surface and have a gas ionizing efficiency about 1000 times higher than that of conventional magnetron discharges. Therefore, low voltage, high current diffused discharges between the anode and the magnetron cathode can be used as an efficient generator of gaseous plasmas for e.g. work piece heating, for sputtering and for increasing the reactivity of reactive gases such as nitrogen and oxygen.

The graph of FIG. 3 shows the sum of single polarity, half period sinusoidal pulses forming periodically occurring pulses having a shape with two steps or levels. This pulse type is the basic pulse used for the method of magnetron sputtering described in the cited International patent application No. WO 02/103078. Hence, the high, second amplitude or level in each driving current pulse can be used for ionization of vapor sputtered by a first lower amplitude or pulse level pulse part and it can also be used for increasing the reactivity of the processes by an increased ionization of the reactive gases. According to that patent application the driving discharge current between anode and magnetron sputtering cathode is periodically modulated to form such two-step pulses. A driving pulse obtained by summing a multitude of half period sinusoidal functions, i.e. half-wave, rectified currents, has, in an advantageous way, a substantially constant current in each of the two phases of the resulting discharge, both for the sputtering phase and the ionizing phase.

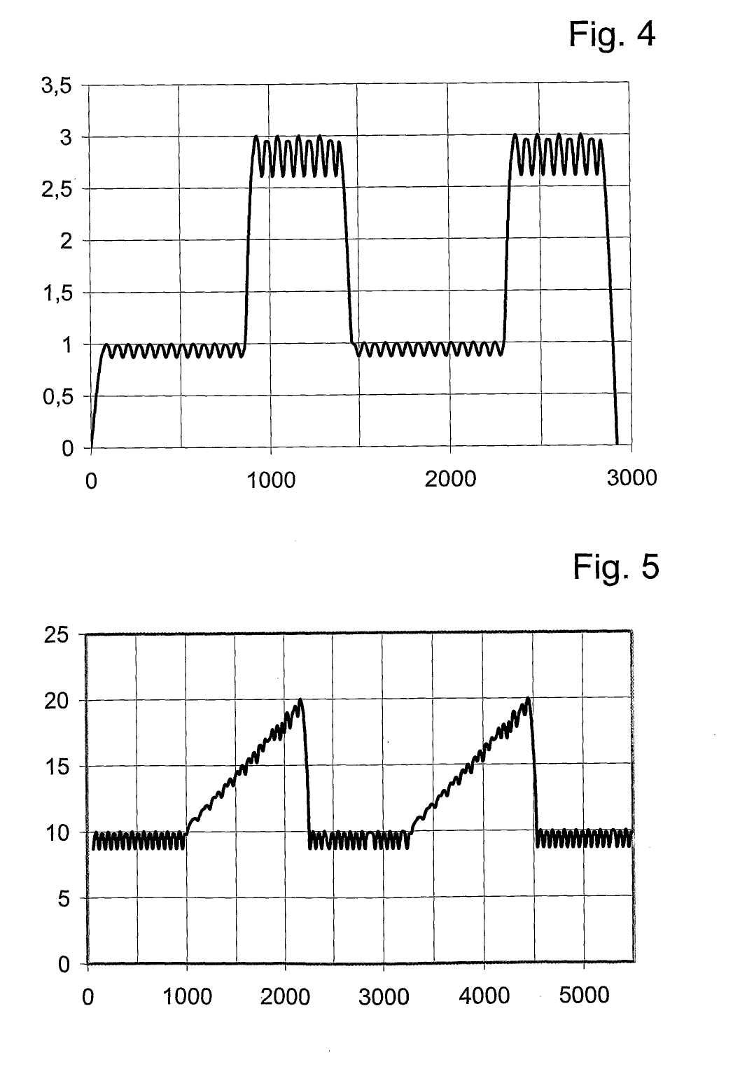

In the diagram of FIG. 4 another sum of single polarity, half period sinusoidal pulses having two different amplitudes is shown, the resulting pulse shape corresponding to two pulses of the kind illustrated in FIG. 3 appearing directly after each other. This sequence of superposed pulses allows, when applied to a magnetron sputtering device, that the formation of monolayers at the cathode surface is avoided and thereby the efficiency of sputtering/deposition processes can be significantly increased. Also, this sequence of pulses allows increasing the efficiency of target vapor ionization and increasing the reactivity of reactive processes, these two effects being the result of the high ionizing efficiency of the low voltage diffused discharges.

It was found that the efficiency of ionizing gas and vapor in low voltage discharges, occurring for the high current level, is about 1000 times higher than that of high voltage discharges, occurring during low current level. However, the characteristic discharge voltage of low voltage discharges is about 50-100 V resulting in a very low sputtering efficiency of such discharges. In contrast, the high voltage discharges, that are usually called magnetron discharges, have a low ionizing efficiency but a high sputtering efficiency. Therefore the combination of high and low voltage discharges allows obtaining both a high rate of the sputter-deposition process and a high reactivity of the produced species because the species are in the plasma phases that have the highest reactivity. The double-step sputtering and ionization process is related to the concept of “time of flight processes”. It means that the phase of sputtered ionized vapor has to be produced in time and space before the vapor leaves the area of discharge energy dissipation. The dimension of this area depends on the magnetron magnetic field topology, the magnetron sputtering cathode dimensions and the cathode material. The characteristic time of flight of vapor passing through the energy dissipating area is in the range of 100 microseconds. The time lengths of the low and high current periods have to be adjusted to be suitable for different sputtering deposition systems.

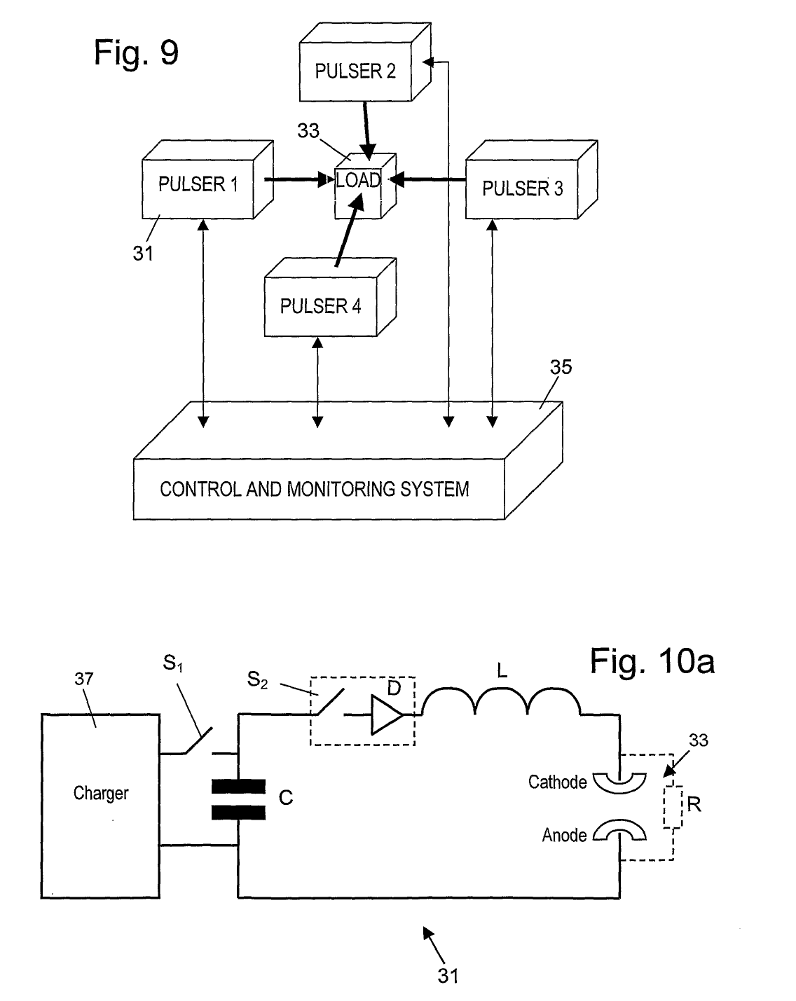

FIG. 5 shows the sum of single polarity, half period sinusoidal pulses having such amplitudes and appearing in time so that substantially triangular pulses are obtained over a substantially constant DC level. This sequence of the pulses works, when applied to a magnetron sputtering device, in a way similar to that of the pulses shown in FIG. 4. The main difference is that an increased amount of target vapor is produced before it is ionized. The triangular pulse shape is achieved by gradually increasing the sputtering current before transition of the magnetron sputtering discharge into a low voltage diffused discharge that is used for efficient vapor ionization. The use of triangular pulse allows that the transition from high to low voltage discharge requires a reduced consumption of energy. Thus, it was found that the transition time, referred to the time when the amplitudes of the element pulses start to increase from the low level, for rectangular double-step pulses and for triangle pulses is almost the same and is in the range of tenth of microseconds but the average power consumption is lower for triangle pulses due to a lower average discharge current during the time period when the transition period occurs. Parameters of the discharges between the anode and the sputtering cathode during the transition period depend on the target material and the magnetron magnetic field strength and therefore the timing and shape parameters of the two-level current pulses and the triangle pulses should be adjustable. These parameters are easily adapted by an electronic control and monitoring system, such as that shown in FIG. 9.

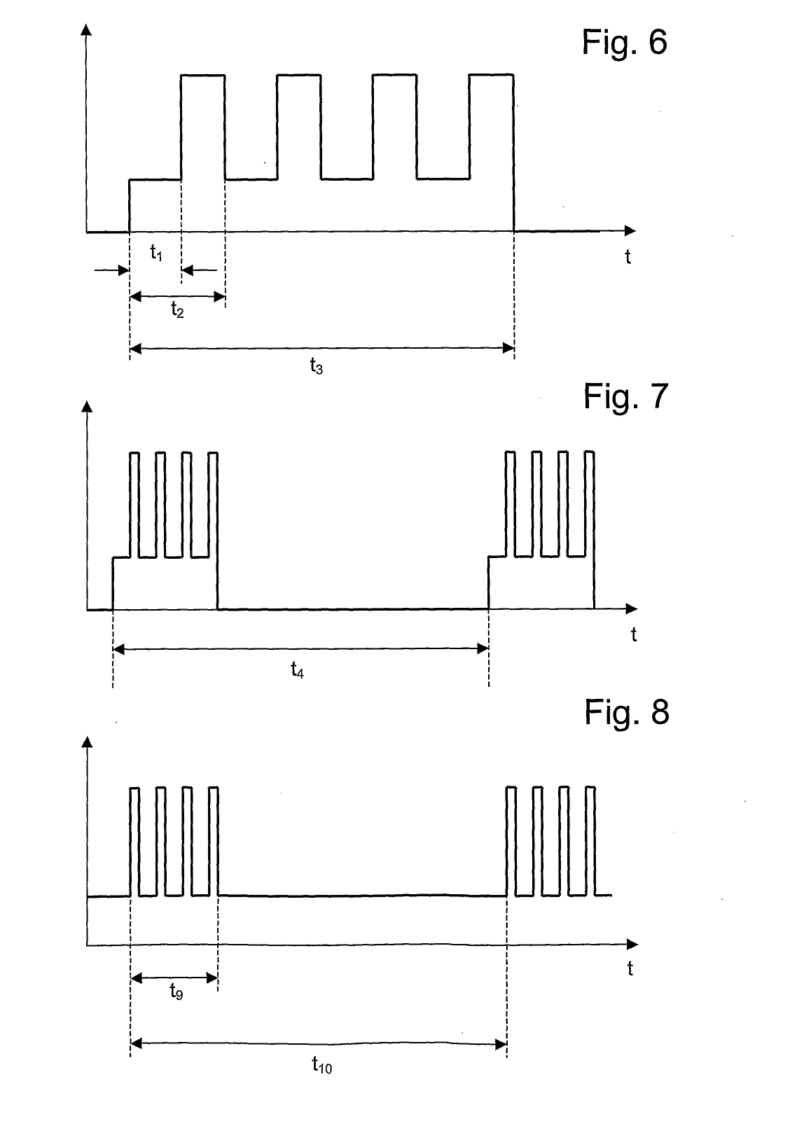

FIG. 6 is a schematic diagram of another pulse shape that can be obtained by summing half-wave sinusoidal pulses having adapted amplitudes and appearing at adapted times. This sequence of pulses is similar to that shown in FIG. 4 but here the constant DC level and the appearing of the superposed rectangular pulses are periodically interrupted to form separate, composite pulses. It was found that, when applied to a magnetron sputtering device, for efficient sputtering and gas and vapor ionization the times t₁ and t₂ of the pulse must be in the range of 1 μs up to 1 ms, the time t₁ being the duration of the time periods between the high level time periods, i.e. the length of the periods with a low current level, and the time t₂ being the repetition time or time periods between the starts of the high level pulses. The time t₃ which is the length of the total pulse must be in the range of 10 μs up to 100 ms. The high and low voltage diffused discharges occur as above substantially for the time periods of the low current level and for the time periods of the high current level, respectively. This pulse shape has advantages compared to the simple two-level pulses as seen in FIG. 3 and disclosed in the cited International patent application No. WO 02/103078. The simple two-level pulses according to prior art have time intervals between which no current is flowing and thus gas layers are formed on the sputtering cathode surface during these intervals between the pulses. For each simple two-level pulse the initial portion of the discharge energy is used for cleaning the cathode surface from adsorbed gas layers. The pulse shape as illustrated in FIG. 6 can be seen as a sequence of a plurality of such simple two-level pulses following directly after each other, without any interruption or time interval between them. The number of simple two-level pulses assembled in one composite pulse or “pulse train” can be selected so that the length of the composite pulses is about 100 ms. This composite pulse shape allows a significant reduction of the part of the discharge energy which is used for sputtering adsorbed gas. In order to achieve the highest possible average of the power of the pulses the time (t₄-t₃) between the composite pulses is much longer than the length t₃ of the composite pulses as illustrated in FIG. 7, t₄ being the repetition time of the composite pulses. Thus, FIG. 7 is a schematic diagram of a sequence of pulses, each similar to the pulse shown in FIG. 6. The ratio t₃ to t₄ is preferably equal to or smaller than 0.5, i.e. t₃/t₄≦0.5.

A further reduction of the influence of the monolayers of adsorbed gas on the sputtering deposition process can be achieved by the pulse shape or shape of the driving discharge current as illustrated in a schematic diagram of FIG. 8. This current can obviously also be obtained by summing half-wave sinusoidal pulses having adapted amplitudes and appearing at adapted times. This current includes bursts of pulses superposed on a DC current having a constant level. It can also be seen as discharge current having a constant low level interrupted by bursts or short sequences of periodically repeated time periods of a higher level, the bursts or short sequences also appearing periodically in time. When applied to a magnetron sputtering device, discharges occur for the low, DC level, in the areas of currents for normal or abnormal glow discharges or high voltage diffused discharges and the discharges for the portions of the higher level of the current, i.e. the areas of the superposed pulses, occur in the area of low voltage, high current diffused discharges. This shape of the discharge current allows achieving a deposition rate which is as high as for a pure DC current having a single constant level but with a significantly increased process reactivity. The increased reactivity is achieved by the periodic efficient ionization of the reactive gas by the low voltage high current discharges occurring during the high level portions. The number of high current pulses in each pulse train or pulse sequence is variable from one up to hundreds and is determined by the required deposition rate and desired process reactivity. In a deposition process some of the different pulse shapes illustrated in FIGS. 1c-8 can be used sequentially for depositing films having different properties. The pulse shapes are easily controlled by the control and monitoring system shown in FIG. 9.

It has been found that combination of parameters as mentioned above for discharges between the anode and the magnetron sputtering cathode allows obtaining high sputter/deposition rates characteristic of DC sputtering, this being combined with a high reactivity of the reactive processes. It was found that for deposition of TiN films the process is very stable and that a variation of the nitrogen content in the process chamber of ±30% of the average value does not result in a variation of the nitrogen content of the produced stoichiometric TiN films.

FIG. 9 is a schematic showing four pulsers 31 connected to the same load 33 and controlled by a control and monitoring system 35. The control and monitoring scheme as performed by the control and monitoring system switches the pursers on one after another. Each of the pulsers can as described above generate in the load half-periods of a sinusoidal current having the same polarity. The pulses generated by the pulsers are shifted in time by e.g. one third of half a sinusoid period. Also, other shifts in time can obviously be used. The pulsers can also be designed to generate other pulse shapes such as substantially exponentially decaying pulses. Preferably, all the pulsers generate pulses having similar shapes or even the same pulse shapes, at least for generating portions of each of the resulting pulses. The sequence of pulsers switching on is, for example, pulser one, pulser two, pulser three, pulser four, pulser one and so on. The number of pulsers is selected so that the time interval between the periodic switching on of each pulser is sufficient to recharge the pulser, in particular the capacitor in it. For a sputtering deposition process using capacitors also the pulse shapes, in particular the amplitude or height of the generated pulses, can be controlled by the control and monitoring system according to the specific process and processing apparatus.

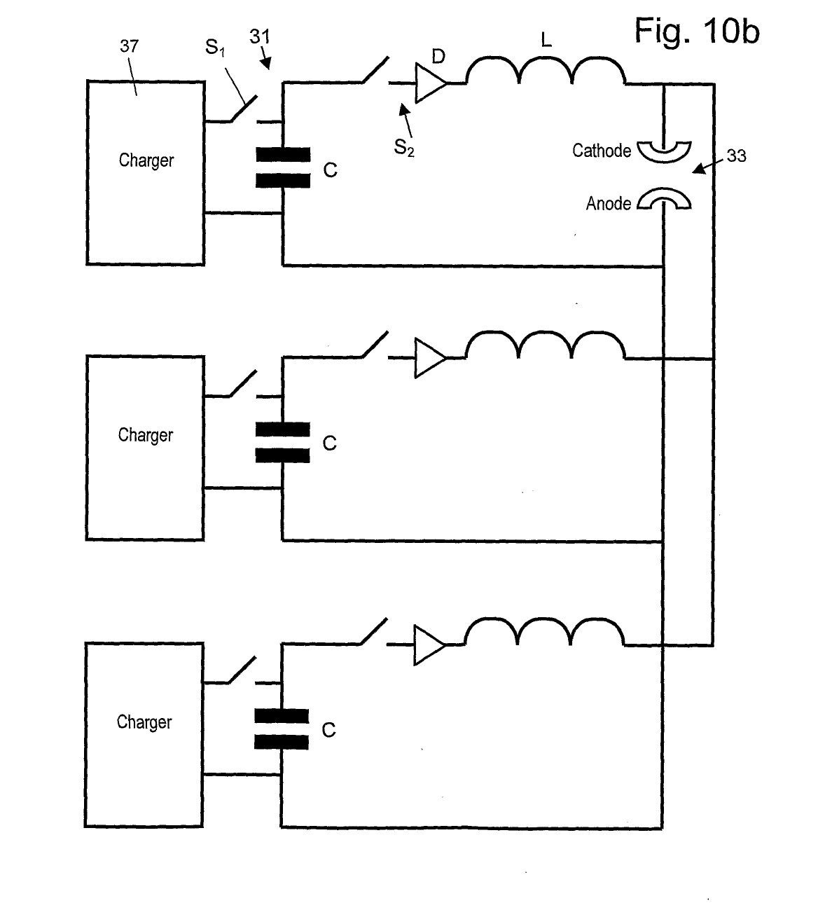

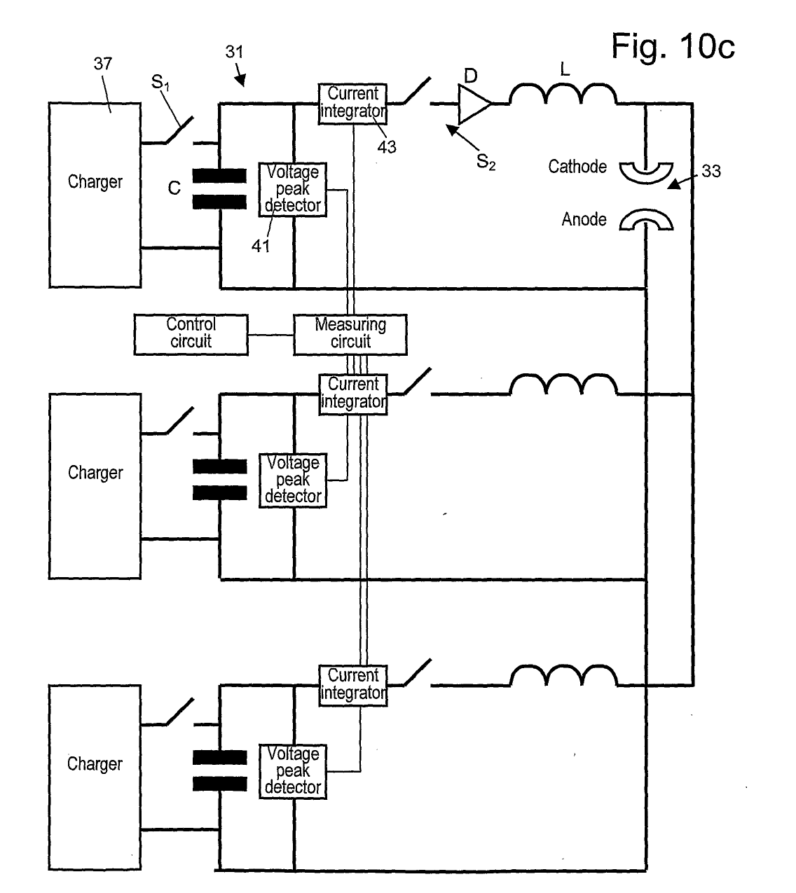

FIG. 10a is a schematic of a single separate pulser 31. The pulser includes a capacitor C, an inductance L, a charger 37 and two electric switches S₁ and S₂. The load 33 is connected in an electric circuit including the capacitor, the inductor and the second electric switch S₂ connected in series with each other, in the circuit shown connected to an end terminal of the inductor L and an end terminal of the capacitor C. The capacitor is periodically charged by the charger 37 by closing the first electric switch S₁. The capacitor C is periodically discharged through the load 33 by closing the second electric switch S₂ that is supposed to have a built-in rectifying capability, indicated in the figure by a diode D. Advantageously, the second switch S₂ is a solid state switch or semiconductor switch such as a thyristor or an IGBT module also acting as a rectifier. The current in the load 33, e.g. its maximum value, is regulated by the voltage over the charged capacitor C, before discharging, as modified by the inductor L. All processes are coordinated by a control and monitoring scheme as commanded by a control and monitoring unit or system 35, not shown in this figure.

For example, three pulsers 31 of the above kind can be connected in parallel to the same anode-cathode gap 33 as seen in FIG. 10b. All switches S₁, S₂ are controlled by the same control unit. Also, all the element pulser circuits can be identical to each other, i.e. have the same values of the components connected in them.

This can be compared to the disclosure of the cited International patent application No. WO 02/103078 according to which, for supplying two-level current pulses according to FIG. 3, a pulsed power supply is used that includes two similar electric circuits connected in parallel to the discharge gap, each circuit generating pulses. One of these circuits supplies the low current used for the first part of the discharge pulse and the other one the higher current used for the second part of the discharge pulse. To supply such a composite pulse the power supply as suggested herein operates in the following way. The capacitors C in all the circuits 31 as connected according to FIG. 10b are repeatedly charged and discharged by connecting/disconnecting the charging switches S₁ and disconnecting/connecting the discharge switches S₂. The discharging switches can e.g. be connected for suitable time periods that are sufficient to allow that the associated discharge capacitor C is discharged to provide current pulses, each having an adapted length such as the length of half a period of a substantially sinusoid oscillation. Obviously, also shorter pulses can be provided if required. To achieve this, the values of the components the parallel discharge circuits are chosen so that, as described above, the ratio R<ρ is valid, where R is the resistance of the circuit including the load resistance, p as above is the quantity (L/C)^{1/2}, L is the circuit inductance and C is the circuit capacitance. The discharge switch S₂ in the first pulser circuit is first connected, i.e. controlled to take a closed or conducting state, during a time period T/2, where T is the period of the sinusoidal oscillation and is equal to T=2π(LC)^{1/2}. Thereupon, the discharge switch S₂ in the second pulser circuit is connected with a delay of T/3 after the discharge switch in the first circuit has been connected. The discharge switch S₂ in the third circuit is connected with a delay of 2·T/3 after the discharge switch in the first circuit was connected. In each of the parallel circuits schemes the charging switch S₁ is connected after the corresponding discharging switch has been disconnected. The charging period of discharge capacitor C in each pulser circuit is, for a delay of T/3 between the discharges, as a maximum equal to (N−1.5)·T/3 where N is the number of parallel discharge circuits 31 connected to the same load. The number N of parallel circuits is chosen so that this time period (N−1.5)·T/3 is sufficient to recharge the capacitors C. This means among other things that if the same discharge circuit has to be discharged at least twice for producing one resulting, combined discharge pulse, at least two parallel discharge circuits 31 must be connected to the discharge gap 33, but in practice at least three parallel discharge circuits are preferably used. For the case of producing two-level pulses at least two element pulses should be used for each level. In that case preferably four parallel discharge circuits 31 are used and then the discharge switch S₂ of the fourth circuit, not shown, is connected with a delay of T/3 after the discharge switch of the third circuit has been connected. The same procedure is successively performed for all the discharge circuits, and if only four circuits are provided, thus, the discharge switch of the first circuit can then be connected with the same delay, provided that the time (N−1.5)·T/3 is sufficient for charging the capacitor C to the required voltage. The voltage to which each discharge capacitor is charged is adapted by varying the charging time.

Now a method of measuring the energy delivered from a pulsed power supply will be described that for each power supply 31 includes two standard circuits, a voltage peak detector 41 and a current integrator 43, see FIG. 10c.

As has been described above, the pulsing for each element pulser circuit 31 is generally made in the way that a capacitor C is charged to a specified voltage and then discharged into the load 33 through a discharge switch S₂. If the time period between discharges is too short it means, as has been indicated above, that the charger 37, which is active charging the capacitor between the discharge periods, may not be capable of charging the capacitor to the desired or required voltage, since the charger circuit generally has a limited capability to deliver electrical current. If a capacitor having the capacitance C has been charged to a voltage U_{c,peak} during a charging time period is t_{c} which thus is the time between discharges the current intensity I_{c} delivered from the charger was:

I_{c}=C·U_{c,peak}/t_{c}

from which is obtained:

U_{c,peak}=(I_{c}/C)·t_{c}

this demonstrating how that the final voltage reached depends on the time period between the discharge periods for producing the output pulses.

The voltage peak detector 41 measures the highest voltage reached at the capacitor C. It is designed to detect the voltage peak value and to provide an output signal proportional to or representing the detected peak value. That is, the voltage peak detector keeps its highest measured value even if the input voltage drops, such as during the discharge period. The voltage peak detector is reset from a measuring circuit 45 connected to control circuit 47 such as a processor and this circuit also samples the output value of the peak detector 41. The measuring circuit 45 and the control circuit 47 are components of the control and monitoring system 35.

The current integrator 43 measures the current flowing in to the capacitor C and gives an output signal proportional to or representing the integrated current over time, which is the total charge Q stored in the capacitor. The integrator output is also, as the voltage detector, read from the measuring circuit and is reset after the reading has been completed. The signal output from the current integrator 43 is locked when the discharge period starts.

By measuring the signal from the current integrator 43 and the signal from the voltage peak detector 41, directly before the capacitor C starts to be discharged, a good measure of the energy that was then stored in the capacitor can be obtained. If it is assumed that the capacitor is fully discharged this will be the energy delivered to the load 33 by each pulse.

Since E=Q·U is the energy stored in a capacitor, Q denoting the charge stored therein and U the voltage over the capacitor, the measuring circuit 45 can sample the output from the voltage peak detector 41 and the current integrator 43 immediately before the capacitor is discharged. Then, the sampled values can be multiplied by each other, in the measuring circuit or the control circuit 47, to obtain a measure of the energy in the pulse applied during the following discharge period.

The integrator and voltage probe are reset during the discharge period by a control signal after the measuring circuit 45 has finished reading the outputs signals thereof.

The measurement of the energy of each applied element pulse can be used in the following way for the simplest case including a combined pulse having a generally rectangular shape, see the diagram of FIGS. 1c, 1d and 2a.

1. The user specifies the total energy of an applied combined pulse, the total pulse length and the repetition frequency.

2. The control and monitoring system 35 control circuit 47 calculates, based on the characteristics of primarily the chargers 37 and the capacitors C, the corresponding lengths of the charging periods and discharging periods and the timing for each element pulse and informs the control circuit 47 thereof.

3. The control circuit 47 controls the switches S₁, S₂ of each element pulser 31 according to the received information CPU, and measures the actually obtained energy of each element pulse, controlling the charging switches S₁, in a feed-back manner according to the measured value of the energy so that the total pulse energy specified by the user is obtained until a steady-state is reached.

It is obvious that the above principle of connecting a plurality of element pulse supplies 31 to the same discharge gap 33 and commanding them to deliver partly overlapping pulses, the overlap generally being relatively large, can be applied to the driving of any discharge gap as long as the pulse supplies can operate substantially independently of each other. For instance, if only arc discharges are desired it may be possible to eliminate the inductors L of FIG. 10b. In the case where the switches S₂ of the circuit in which the discharge gap 33 is connected have no rectifying capability, to achieve the desired independency of the pulse supplies, suitable diodes, not shown, can be used.

1. A method of producing electric discharges between electrodes, in particular in laser tubes, flashlamps and magnetron sputtering devices, such as for producing discharges in a gas and/or in a vapor of a solid material, characterized by the steps of:
providing element electric pulses from a plurality of electric pulse sources, in particular three or more electric pulse sources,
summing the element electric pulses to form resulting electric pulses, each of the resulting electric pulses having at least partly a substantially constant level, the substantially constant level being formed from at least two element electric pulses having the same pulse height or pulse amplitude, and
applying the resulting electric pulses to the electrodes to produce electric discharges.

2. A method according to claim 1, characterized in that in providing the element electric pulses, the shapes, in particular the peak levels or amplitudes, of the element electric pulses are controlled to produce, when summed, resulting electric pulses having a desired shape.

3. A method according to claim 1, characterized in that in providing the element electric pulses, the starts of the element electric pulses are controlled to produce, when summed, to produce resulting electric pulses having desired start times and a desired shape.

4. A method according to claim 1, characterized in that in providing the element electric pulses, the ends of the element electric pulses are controlled to produce, when summed, to produce resulting electric pulses having a desired shape.

5. A method according to claim 1, characterized in that in providing the element electric pulses, the element electric pulses are provided as pulses having the same polarity.

6. A method according to claim 1, characterized in that in providing the element electric pulses, the element electric pulses are provided as pulses having shapes of half of sinusoidal waves, in particular sinusoidal waves having the same frequency or the same period.

7. A method according to claim 6, characterized in that in providing the element electric pulses, the time interval between starts of sequential element electric pulses is smaller than ½ of a sinusoid period, in particular smaller than 0.4 of a sinusoid period and preferably not larger than one third of a sinusoid period.

8. A method according to claim 6, characterized in that in providing the element electric pulses, the time interval between starts of sequential element electric pulses is in the range of ⅙-½ or 0.28-0.4 of a sinusoid period, in particular substantially equal to one third of a sinusoid period.

9. A method according to claim 1, characterized in that in providing the element electric pulses, the element electric pulses are provided by discharging elements capable of storing electric energy, in particular capacitors or inductors.

10. A method according to claim 1, characterized in that in providing the element electric pulses, the element electric pulses are provided by discharging capacitors through inductors.

11. A method according to claim 10, characterized in that before discharging the capacitors, the capacitors are charged to controlled, adapted voltages.

12. A method of magnetron sputtering comprising the steps of:
providing sputtering and possibly reactive gases and a work piece in a processing chamber,
producing driving electric pulses, each having at least partly a substantially constant level,
applying the driving electric pulses to create discharges in the processing chamber between an anode and a magnetron sputtering cathode,
characterized in that in producing the driving electric pulses, the driving electric pulses are obtained by summing element electric pulses generated by a plurality of electric pulse sources, the substantially constant level being formed from at least two element electric pulses having the same pulse height or pulse amplitude.

13. A method according to claim 12, characterized in that in providing the element electric pulses, the element electric pulses are provided as current pulses having an amplitude or pulse height not larger than 10 kA.

14. A method according to claim 12, characterized in that in providing the element electric pulses, numbers of sequential or consecutive element electric pulses are provided to have amplitudes or pulse heights varying in the time as a single step square function or a rectangular function, or as a two step square function.

15. A method according to claim 12, characterized in that in providing the element electric pulses, numbers of sequential or consecutive element electric pulses are provided to have amplitudes or pulse heights varying in the time as a two step square function, so that consecutive ones of said two step square functions follow directly after each other with no gap, for at least a repeated number of said two step square functions.

16. A method according to claim 15, characterized in that the total time t of said repeated number of said two step square functions is in the range of 10 microseconds to 1 second.

17. A method according to claim 15, characterized in that the gap time T between said repeated numbers of said two step square functions is in the range of 100 microseconds to 10 seconds.

18. A method according to claim 15, characterized in that the ratio t/T is smaller than 0.5 where t is the total time each of said repeated number of said two step square functions and T is the gap time between said repeated numbers of said two step square functions.

19. A pulsed power supply assembly for connection to a discharge unit to produce electric discharges between electrodes, in particular to laser tubes, flashlamps and magnetron sputtering devices, such as for producing discharges in a gas and/or a vapor of a solid material, characterized by a plurality of element electric pulsed power supplies, in particular three or more electric pulsed power supplies, each providing element electric pulses, the element electric pulsed power supplies connected to each other to form resulting electric pulses by summing the element electric pulses, so that each of the resulting electric pulses have at least partly a substantially constant level, the substantially constant level being formed from at least two element electric pulses having the same pulse height or pulse amplitude and obtained from different pulsers.

20. A pulsed power supply assembly according to claim 19, characterized by a control and monitoring unit connected to each of the element electric pulsed power supplies to control the start, end and/or amplitude or pulse height of the element electric pulses.

21. A pulsed power supply assembly according to claim 19, characterized in that each of the element pulsed power supplies includes a harmonic oscillator.

22. A pulsed power supply assembly according to claim 19, characterized in that each of the element pulsed power supplies includes a dischargeable storage for electric energy, in particular a capacitor or an inductor.

23. A pulsed power supply assembly according to claim 19, characterized in that each of the element pulsed power supplies includes a capacitor arranged to be discharged through an inductor.

24. A magnetron sputtering device including a pulsed power supply assembly according to claim 19.
